(19) United States
(12) Patent Application Publication
(10) Pub. No.: US 2014/0113428 A1
(43) Pub. Date: Apr. 24, 2014

(54) Method for Integrating MnOz Based Resistive Memory with Copper Interconnection Back-End Process

(71) Applicants: Yinyin Lin, Shanghai (CN); Xiaopeng Tian, Shanghai (CN)

(72) Inventors: Yinyin Lin, Shanghai (CN); Xiaopeng Tian, Shanghai (CN)

(73) Assignee: FUDAN UNIVERSITY, Shanghai (CN)

(21) Appl. No.: 13/381,463

(22) PCT Filed: Jul. 6, 2011
(86) PCT No.: PCT/CN11/01112

§ 371 Date: Feb. 7, 2012

(51) Int. Cl. H01L 45/00

(52) U.S. Cl. CPC H01L 45/1253
USPC 438/382

(57) ABSTRACT

The present invention pertains to the technical field of semiconductor memory. More particularly, the invention relates to a method for integrating MnO_{z} based resistive memory with copper interconnection back-end process. In the method for integrating with the process, a MnSi compound layer is firstly formed by silicifying Mn metal in the cap layer on Cu wire, a MnSiₓO_{y} storage medium layer is formed by oxidizing the MnSi compound layer, and a MnSiO compound layer serves as a barrier layer for Cu wire in the copper interconnection back-end. The method has the advantage of be easily compatible with a copper interconnection back-end process at or below 45 nm process node. The MnO_{z} based resistive memory is low in fabrication cost, high in reliability and low in power consumption.

### FIELD OF THE INVENTION

The present invention pertains to the technical field of semiconductor memory, and relates to a resistive memory based on MnSiₓO_{y} storage medium layer (0.001<x≦2, 2<y≦5), and in particular to a method for integrating resistive memory based on MnSiₓO_{y} storage medium layer with copper interconnection back-end process

### BACKGROUND

Memories have possessed an important position in the market of semiconductors. Due to increasing popularity of portable electronic devices, non-volatile memories have occupied a larger and larger share in the whole market of memory; wherein over 90% shares are held by FLASH. However, due to requirements on storage charge, the floating gate of FLASH cannot be made thinner limitlessly with the development of technology generations. It is reported that the limit of FLASH technology is predicted to be at around 32 nm. Thus, it is urgent to seek a next generation of non-volatile memory having a more superior performance. Recently, resistive switching memory has drawn high degree of attention due to such characteristics as high density, low cost, and being able to break through limitations on development of technical generations. Materials used by resistive switching memory comprises phase-transition material, doped SrZrO₃, Ferroelectric material PbZrTiO₃, Ferromagnetic material Pr₁₋ₓCaₓMnO₃, binary metal oxide material, organic material, etc.

Resistive memory switches between a high resistance state (HRS) and a low resistance state (LRS) in a reversible manner under the effect of electrical signal, thereby realizing storage function. The storage medium material used by resistive memory can be various semiconductor metal oxide materials such as Copper oxide, Titanium oxide, Tungsten oxide, etc.

Meanwhile, we note that with respect to MnO_{z} (1<z≦3) material which is one of binary metal oxide, the resistance switching characteristic thereof has been reported by SenZhang et al. in a document entitled “Resistive switching characteristics of MnO_{z}-based ReRAM” in J. Phys. D: Appl. Phys. 42 (2009). Therefore, MnO_{z} can be used as storage medium for resistive memory. As can be seen from the document, the resistance of MnO_{z} based resistive memory in low resistance state is smaller than 100Ω, which will consequentially result in a large current in low resistance state and confine low power consumption application of the resistive memory.

Furthermore, with the development of semiconductor process technology, key sizes are being reduced continuously, and it is necessary that resistive memory technology extends post the process node of 45 nm. Due to limitations of grain size, corresponding oxides of materials of Cu, W, etc., when used as storage medium, will result in a large leaking current, thus increasing power consumption and making it impossible to replace FLASH effectively in the stages of 45 nm and 32 nm. Moreover, at the process node of 45 nm and 32 nm, it is required to reduce the thickness of barrier layer in copper interconnection structure to be 4.9 nm and 3.6 nm respectively and further increase the ratio between depth and width. Traditional Ti/TiN, Ta/TaN, etc., can not meet such requirements. Therefore, the application of storage medium such as TiOₓ and TaOₓ in copper interconnection back-end will also be restricted by art process.

However, MnSiO compound material may be widely used as copper diffusion barrier material when post 45 nm process node. MnSiO compound material has such advantages as being low in resistivity, being able to block copper diffusion effectively, having a good characteristic of electromigration resistance, as well a super slim thickness and high reliability.

### SUMMARY OF THE INVENTION

The objective of the invention is to propose a method for integrating MnO_{z} based resistive memory with copper interconnection back-end process.

In order to achieve the above objective or other objectives, the invention provides the following technical solution.

The method for integrating MnO_{z} based resistive memory with copper interconnection back-end process provided by the invention comprises the following steps:

(1) pattern-forming Cu wire having MnSiO compound layer as barrier layer;

(2) cover-depositing cap layer on the Cu wire;

(3) pattern-etching the cap layer to form apertures so as to expose Cu wire region where MnSiₓO_{y} storage medium layer is intended to be formed;

(4) filling Mn metal layer in the apertures of the cap layer;

(5) silicifying the Mn metal layer to form MnSi compound layer;

(6) oxidizing the MnSi compound layer to form MnSiₓO_{y} storage medium layer;

(7) pattern-forming an upper electrode on the MnSiₓO_{y} storage medium layer; and

(8) continuing with the copper interconnection back-end process to form copper plug and a next layer of Cu wire;

wherein 0.001<x≦2, 2<y≦5.

As a preferred embodiment, the copper interconnection back-end process is a process at or below 45 nm process node.

As a preferred embodiment, specifically, said step (1) comprises the following steps:

(1a) depositing seed crystal layer of CuMn alloy in the trench;

(1b) electroplating copper;

(1c) annealing copper and the seed crystal layer of CuMn alloy;

(1d) conducting planarization to remove excessive copper and copper oxide and Mn oxide in the surface of Cu wire.

According to the method provided by the invention, said silicifying could be silicifying in silicon containing gas, silicifying in silicon plasma or ion implantation silicifying of silicon. Said oxidizing could be one of plasma oxidizing, heat oxidizing, ion implantation oxidizing.

According to an embodiment of the method provided by the invention, the upper electrode is a metal layer of TaN, Ta, TiN, Ti, W, Al, Ni, C or Mn, or a complex layer composed of a plurality of layers of the above metal layers.

The Mn metal layer is obtained by sputtering, evaporation or electroplating depositing. The thickness range of Mn metal layer is from about 0.5 nm to about 50 nm.

The MnSiₓO_{y} storage medium layer can be a storage medium layer formed by doping Si into MnO_{z}, wherein 1<z≦3; or the MnSiₓO_{y} storage medium layer is a nano complex layer of MnO_{z} and silicon oxide, wherein 1<z≦3.

According to an embodiment of the method provided by the invention, the copper interconnection back-end process employs dual Damascene process.

The technical effect brought about by the invention will be described as follows: by integrating MnO_{z} based resistive memory with a copper interconnection back-end process, the resistive memory with MIM (metal-insulator-metal) structure is embedded into the copper interconnection back-end structure of logic circuit, especially into a copper interconnection back-end structure at or below 45 nm process node. Therefore, a perfect compatibility of logic process and memory manufacture process can be achieved so that manufacture cost is reduced. On the other hand, since a process of first silicifying and then oxidizing Mn metal layer is employed for MnO_{z} based resistive memory, the speed of oxidizing is relatively slow, the controllability of process is better, and the yield rate and reliability of MnSiₓO_{y} storage medium layer are improved; moreover, due to the relative denser characteristic of MnSi, the MnSiₓO_{y} storage medium layer after oxidization is more dense than common Mn oxides. Thus, resistances in both high resistance state and low resistance state are improved (especially in low resistance state), thereby lowering power consumption of memory unit.

### BRIEF DESCRIPTION OF THE DRAWINGS

The above and other objectives and advantages of the invention will become more fully apparent from the following detailed description with reference to accompanying drawings, wherein identical or similar elements are denoted by identical signs.

FIG. 1 is a schematic structural view showing a resistive memory prepared by the method of integrating MnO_{z} based resistive memory with a copper interconnection back-end process provided by the invention.

FIG. 2 is a schematic structural view showing performing conventional Damascene copper interconnection process until the beginning of a first layer of copper wiring fabrication;

FIG. 3 is a schematic structural view after formation of Cu wire;

FIG. 4 is a schematic structural view after covering a cap layer on the Cu wire;

FIG. 5 is a schematic structural view showing exposing part of Cu wire region after pattern-etching the cap layer;

FIG. 6 is a schematic structural view after filling Mn metal layer in the apertures of the cap layer;

FIG. 7 is a schematic structural view showing forming a MnSi compound layer by silicifying Mn metal layer in the apertures of the cap layer;

FIG. 8 is a schematic structural view after formation of MnSiₓO_{y} storage medium layer;

FIG. 9 is a schematic structural view showing pattern-forming an upper electrode on the MnSiₓO_{y} storage medium layer;

FIG. 10 is a schematic structural view after cover-forming a protective medium layer on the upper electrode;

FIG. 11 is a schematic structural view after cover-forming a medium layer on the protective medium for forming copper plug and Cu wire;

FIG. 12 is a schematic structural view after formation of the copper plug and Cu wire.

### DETAILED DESCRIPTION OF THE INVENTION

The invention will be more fully described in exemplary embodiments with reference to accompanying drawings hereinafter. While the invention provides preferred embodiments, it is not intended that the invention is limited to the described embodiments. For clarity, the thicknesses of layers and regions have been exaggerated in the drawings. However, it should not be construed that these schematic views strictly reflect proportional relationship between geometrical dimensions.

Herein, the reference views are schematic views of idealized embodiments of the invention. The illustrated embodiments of the invention should not be considered to be merely limited to the particular shapes of regions shown in the drawings. Rather, the invention comprises various shapes that can be derived, such as deviations caused during manufacture. For example, a profile obtained by dry etching generally has such characteristics of being curved or rounded. However, they are all represented by a rectangle in the drawings of embodiments, of the invention. The illustrations in the drawings are schematic and should not be construed as limiting the scope of invention.

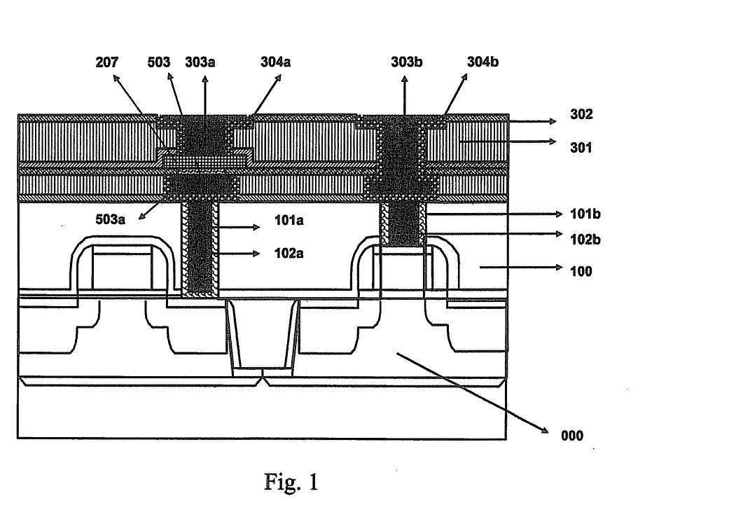

FIG. 1 is a schematic structural view showing a resistive memory prepared by the method of integrating MnO_{z} based resistive memory with a copper interconnection back-end process provided by the invention. As shown in FIG. 1, the MnO_{z} based resistive memory is integrated into a copper interconnection structure, whereby an integrated fabrication of memory and CMOS logic circuit can be achieved. The MnO_{z} based resistive memory uses MnSiₓO_{y} as storage medium layer, wherein x and y reflect stoichiometric ratio among Mn, Si and O, 0.001<x≦2, 2<y≦5. Therefore, the MnSiₓO_{y} storage medium layer 503 can also be considered as a MnO_{z} based storage medium layer containing doped Si. In this embodiment, the MnSiₓO_{y} storage medium layer 503 is formed above the Cu wire 203a in the copper interconnect structure and below the copper plug 303a in the copper interconnect structure, and an optional upper electrode 207 is formed between the copper plug 303a and the MnSiₓO_{y} storage medium layer 503. Preferably, the copper interconnect structure shown in the figure is a copper interconnect structure formed at or below 45 nm process node, wherein all the diffusion barrier layers are MnSiO compound thin film layer which mainly serves to block diffusion of copper into dielectric layer. The specific structure and composition ratio of MnSiO compound thin film layer are different from MnSiₓO_{y} storage medium layer 503.

As shown in FIG. 1, a PMD layer 100 is formed on MOS device. The PMD layer 100 could be dielectric material such as p-doped silicon oxide (PSG). A Tungsten plug 102a and 102b are formed in the PMD layer 100. The Tungsten plug connects a first layer of Cu wire with MOS transistor source or drain on the substrate 000. A diffusion barrier layer 101 for blocking diffusion of Tungsten is provided between the Tungsten plug and PMD medium layer 100. The diffusion barrier layer 101 could be a TaN, Ta/TaN complex layer or Ti/TiN complex layer, or other conductive materials which function as well, such as TiSiN, WNx, WNₓC_{y}, Ru, TiZr/TiZrN, etc. Cu wire 203 is on top of Tungsten plug 102. A diffusion barrier layer is provided between the Cu wire and W plug (Tungsten plug) for preventing Cu from diffusing. In the embodiment shown in FIG. 1, the Cu wire 203a is the lower electrode of the resistive memory.

The MnSiₓO_{y} storage medium layer 503 is formed in a process in which Mn metal layer is silicified first and then oxidized. The thickness range of the MnSiₓO_{y} storage medium layer 503 is 0.5 nm˜50 nm, e.g., 1 nm. By exposing the MnSi compound layer 502 into oxygen atmosphere or ion plasma, Mn in the MnSi compound layer 502 will continuously react with O to produce MnO_{z} compound (1<z≦3), and original Si element exists in MnO_{z} compound material in the form of Si or silicon oxide to form MnSiₓO_{y} storage medium, i.e., MnO_{z} based storage medium layer 503 containing doped Si. In the MnO_{z} based storage medium layer 503, according to the form in which Si exists, MnO_{z} based storage medium containing doped Si could be storage medium of MnO_{z} material doped with Si, or it could be considered as a nano complex layer of MnO_{z} and silicon oxide. The range of percentage of Si element content in MnSiₓO_{y} storage medium layer by weight is 0.001%-60%, and is specifically relevant to stoichiometric ratio of MnSi layer and process conditions of oxidizing. Preferably, the range of percentage of Si content in MnSiₓO_{y} storage medium layer by weight is 0.1% or 1%; and the distribution of percentage of Si content in MnSiₓO_{y} storage medium layer 503 by weight is not necessarily even. For example, it is possible that Si element is distributed in the MnSiₓO_{y} storage medium layer 503 in a form in which the gradient of weight percentage is gradually reduced from an upper surface to a lower surface; it is also possible that Si element is distributed in a physical layer region between the upper surface and the lower surface of the MnSiₓO_{y} storage medium layer 503 in a relatively concentrated manner. For example, the upper surface layer of the MnSiₓO_{y} storage medium layer 503 is MnO_{z} the intermediate layer is MnO_{z} containing silicon layer, and the lower surface layer is MnO_{z}. However, there is no explicit physical boundary among the upper surface layer, the intermediate layer and the lower surface layer, and therefore they all belong to the MnSiₓO_{y} storage medium layer 503. The specific distribution manner of Si element in the MnSiₓO_{y} storage medium layer 503 is not restricted by the invention. It is further noted that in addition to Si element, the MnSiₓO_{y} storage medium layer 503 may further comprise other doped elements. For example, if other active gases such as F containing gas are introduced into oxidizing gas in addition to oxygen during oxidizing process, the MnO_{z} based storage medium will be doped with F in addition to contained Si. Other doped components of specific MnSiₓO_{y} storage medium layer 503 are not restricted by the embodiment of the invention and are relevant to process conditions of oxidizing.

The upper electrode 207 covers the MnSiₓO_{y} storage medium layer 503. The upper electrode 207 could be conductive materials such as TaN, Ta, TiN, Ti, W, Cu, Ni, Co, Mn, etc, or a complex layer composed of the above conductive materials. A copper plug 303a which is fabricated by Damascene process is at the top of the upper electrode 207. The bottom of the copper plug 303a is directly connected with the upper electrode 207. An inter-layer dielectric layer 301 is around interconnecting wires. The inter-layer dielectric layer 301 can be made of various low-k materials, such as SiCOH, etc.

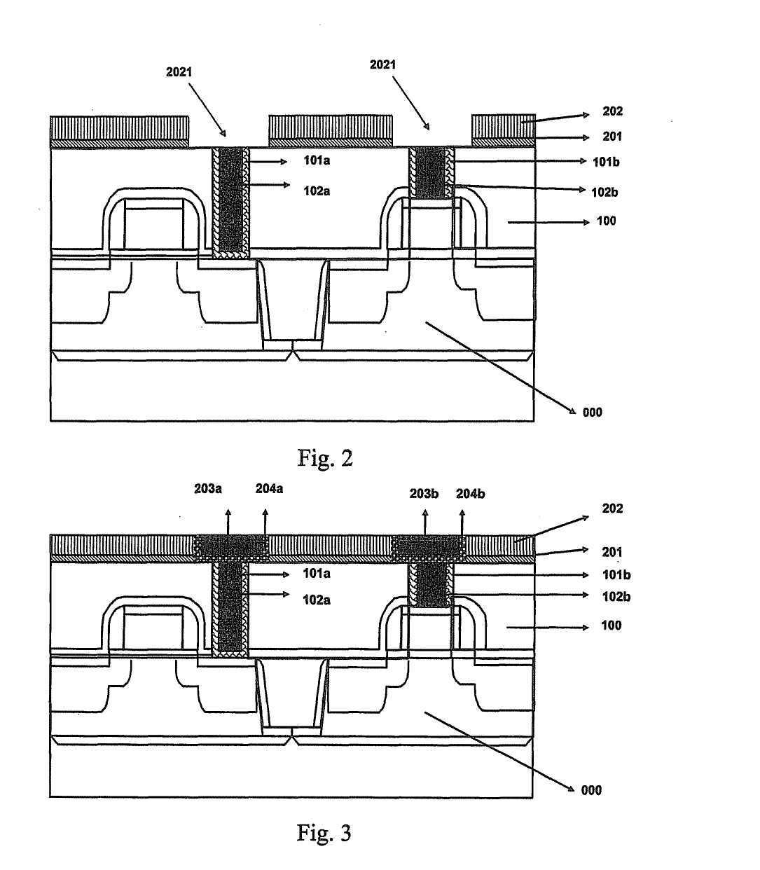

FIGS. 2-12 schematically illustrate the method of integrating MnO_{z} based resistive memory with a copper interconnection back-end process in schematic structural views. The method of the invention will be specifically described with particular reference to FIGS. 2-12.

Firstly, at step S10, a structure is provided for preparing to fabricate Cu wire in conventional Damascene copper interconnection process.

With reference to FIG. 2, a schematic structural view shows performing conventional Damascene copper interconnection process until the beginning of a first layer of copper wiring fabrication. It is preferred to employ conventional dual Damascene process in this embodiment. After the deposition of the etching stop layer 201 and inter-layer dielectric (IMD) 202 is completed, a trench 2021 for forming Cu wire is formed by pattern-etching the etching stop layer 201 and inter-layer dielectric 202. As shown in FIG. 2, 100 denotes the PMD layer, which refers to a dielectric layer between the first layer of wiring and MOS device and could be dielectric materials such as p-doped silicon oxide; a Tungsten plug 102a and 102b is formed in the PMD layer 100. The Tungsten plug 102a and 102b serves to connect the first layer of Cu wire with source or drain of MOS transistor. A diffusion barrier layer 101 (101a and 101b) for preventing Tungsten diffusion is located between the Tungsten plug and PMD dielectric layer 100. The diffusion barrier layer 101 could be TaN, Ta/TaN complex layer or Ti/TiN complex layer, or other conductive materials which function as well, such as TiSiN, WNx, WNxCy, Ru, TiZr/TiZrN, etc; a sealing layer or etching stop layer 201 covers on top of the Tungsten plug. The sealing layer or etching stop layer 201 could be SiN, SiC, or other materials which function as well; an interconnection wire medium layer is on top of the etching stop layer. The interconnect wiring dielectric layer could be low-k materials such as FSG, USG, etc. or other materials which function as well.

Further, at step S20, a Cu wire having MnSiO compound as barrier layer is formed by patterning.

Reference in now made to FIG. 3, which shows a schematic structural view after the formation of Cu wire. It is preferred in the step that the Cu wire (203a, 203b) having MnSiO compound as barrier layer (204a, 204b) is formed by the following method steps:

S201: depositing seed crystal layer of CuMn alloy in the trench;

The step of depositing seed crystal layer of CuMn alloy can be performed by processes such as sputtering, electron beam evaporation, atomic layer deposition or electroplating; the aim of depositing seed crystal layer of CuMn alloy is to form a super slim MnSiO compound as barrier layer by a reaction of Mn diffused to sidewall and SiO at the sidewall during a subsequent annealing process; meanwhile, this barrier layer can also induce copper crystallization when electroplating. The thickness range of seed crystal layer of CuMn alloy is from 5 nm to 100 nm and is preferably about 10 nm; the atomic content of Mn in CuMn alloy is from 0.05% to 20%.

S202: electroplating Cu;

S203: annealing Cu and CuMn alloy layer;

In this embodiment, the annealing process has three functions: firstly, it could eliminate defects in seed crystal layer of CuMn alloy and in electroplated Cu so that resistivity of Cu wire is reduced; secondly, it could promote Mn atoms in seed crystal layer of CuMn alloy to diffuse to sidewall to react with SiO in the sidewall so that a super slim MnSiO compound is formed, thereby a barrier layer (204a and 204b) of MnSiO compound is formed; thirdly, it could promote Mn atoms that have not reacted with SiO in the sidewall to diffuse to Cu surface to form MnO_{z} (1<z≦3), thereby removing excessive Mn atoms in Cu wire.

As compared with prior Ta/TaN barrier layer, the barrier layer of MnSiO compound layer formed by the above method is thinner, simple in fabrication process and has a better evenness. Therefore, the ratio of Cu in trench can be increased, interconnecting resistance can be effectively reduces and interconnection delay is thereby reduced; it is very suitable for a copper interconnection process at or below 45 nm process node.

S204: performing planarizing so as to remove excessive copper and CuO and MnO in the Cu wire surface.

Further, at step S30, a cap layer is cover-deposited on the Cu wire.

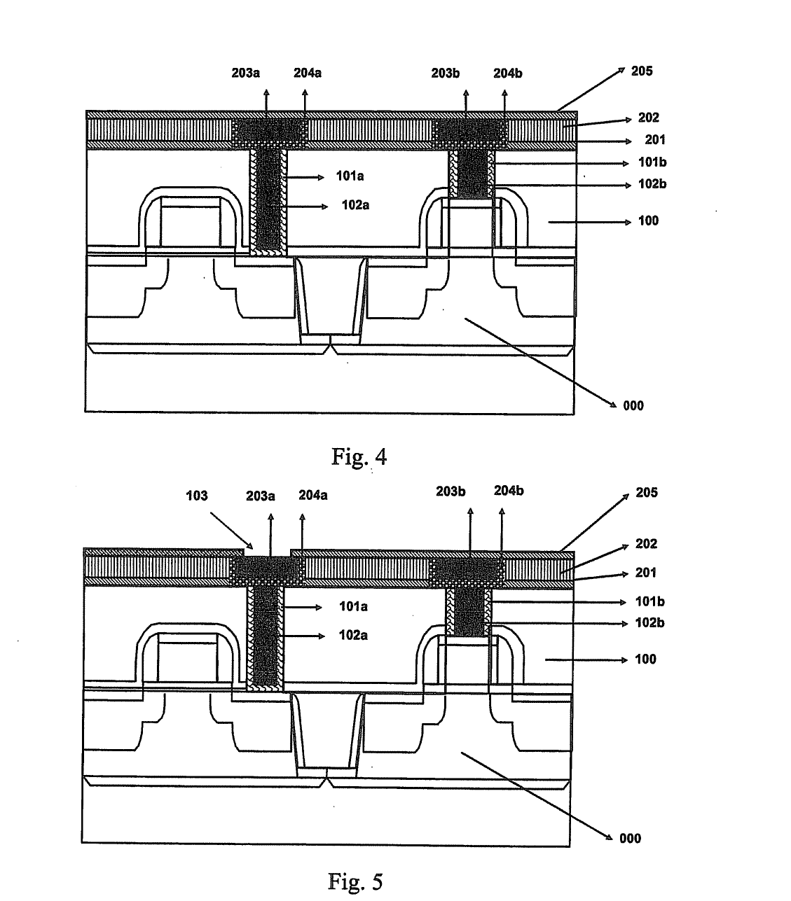

Reference is now made to FIG. 4, which shows a schematic structural view after covering the cap layer on the Cu wire. A layer of cap layer 205 covers on top of the copper plug 203a and 203b. The cap layer 205 could be Si₃N₄, SiON, SiCN, SiC, SiO₂ or a complex layer containing one of them. In this embodiment, some Cu wires only use as logic circuit and do not function as forming memory, e.g., Cu wire 203b; while some Cu wires are simultaneously formed with memories thereon, e.g., Cu wire 203a. In the subsequent steps, the cap layer 205 may be used to protect Cu plug 203b which do not need to form MnSiₓO_{y} storage medium layer.

Further, at step S40, the cap layer is pattern-etched to form apertures so as to expose Cu wire region where the MnSiₓO_{y} storage medium layer is intended to be formed.

Reference is now made to FIG. 5, which is a schematic structural view showing exposing part of Cu wire region after pattern-etching the cap layer. In this embodiment, the apertures 103 expose Cu wire 203a so as to get prepared for the next step of forming storage medium layer. The amount of area and shape of apertures 103 is consistent with that of the MnSiₓO_{y} storage medium layer intended to be formed.

Further, at step S50, a Mn metal layer is filled in the apertures of the cap layer.

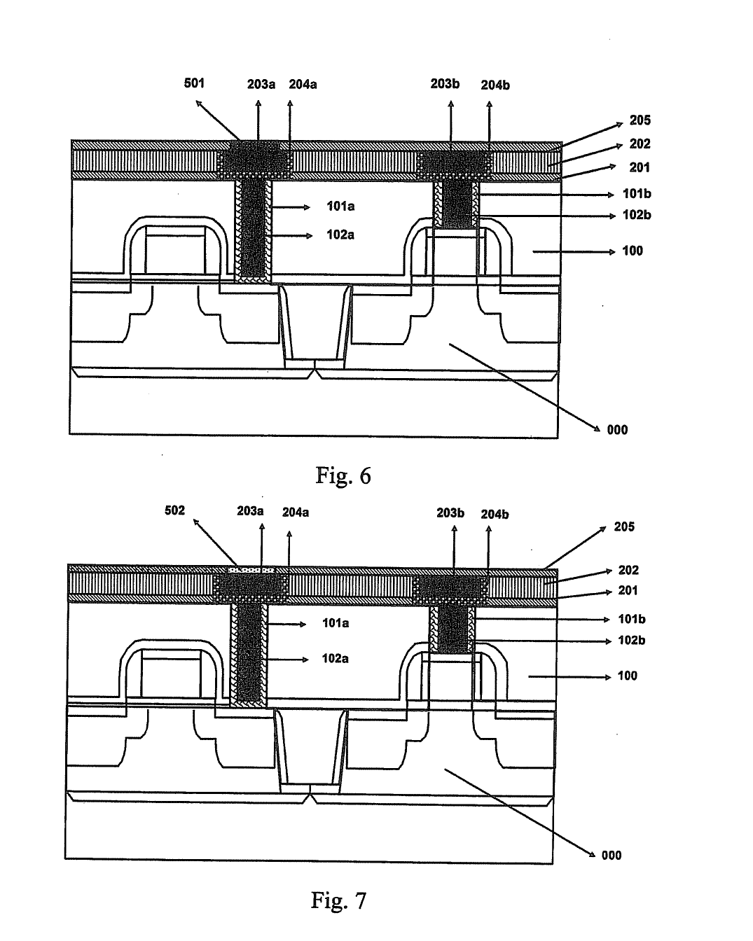

Reference is now made to FIG. 6, which is a schematic structural view after filling Mn metal layer in the apertures of the cap layer. Firstly, Mn metal is covered, which could be done by sputtering, evaporation, electroplating, etc; then excessive Mn metal on the cap layer is removed by planarization process so as to form Mn metal layer 501. For example, a planarization process of Chemical Mechanical Polishing (CMP) is employed, wherein the cap layer is used as polishing stop layer. The thickness of the Mn metal layer 501 is relevant to the thickness of the cap layer and the thickness range could be from about 0.5 nm to about 50 nm, preferably about 5 nm.

Further, at step S60, the Mn metal layer is silicified to form MnSi compound layer.

Reference is now made to FIG. 7, which is a schematic structural view showing forming a MnSi compound layer 502 by silicifying Mn metal layer in the apertures of the cap layer. The MnSi compound layer 502 is formed by silicifying exposed Mn metal layer 501. The methods of silicifying mainly comprises: (1) silicifying in silicon containing gas at high temperature; (2) silicifying in silicon plasma at high temperature; (3) silicifying by silicon ion implantation. The following takes the method (1) of silicifying as an example. By exposing Mn metal layer 501 in silicon containing gas at a certain high temperature (200° C.-600° C.), Mn metal reacts chemically with the gas and is silicified to form MnSi compound layer. In this embodiment, the silicon containing gas could be SiH₄, SiH₂Cl₂, Si(CH₃)₄, etc. The constant gas pressure during the chemical reaction is lower than 20 Torr. The reaction could occur in a SiH₄ atmosphere in a heated condition with the temperature between 100° C.-500° C. and SiH₄ concentration between 0.01%-30%. In the method (3), when silicon ions are implanted, the cap layer 205 could simultaneously serve as a mask layer so as to protect Cu wire 203b on which it is not required to form MnSiₓO_{y} storage medium layer.

Further, at step S70, the MnSi compound layer is oxidized in order to form the MnSiₓO_{y} storage medium layer.

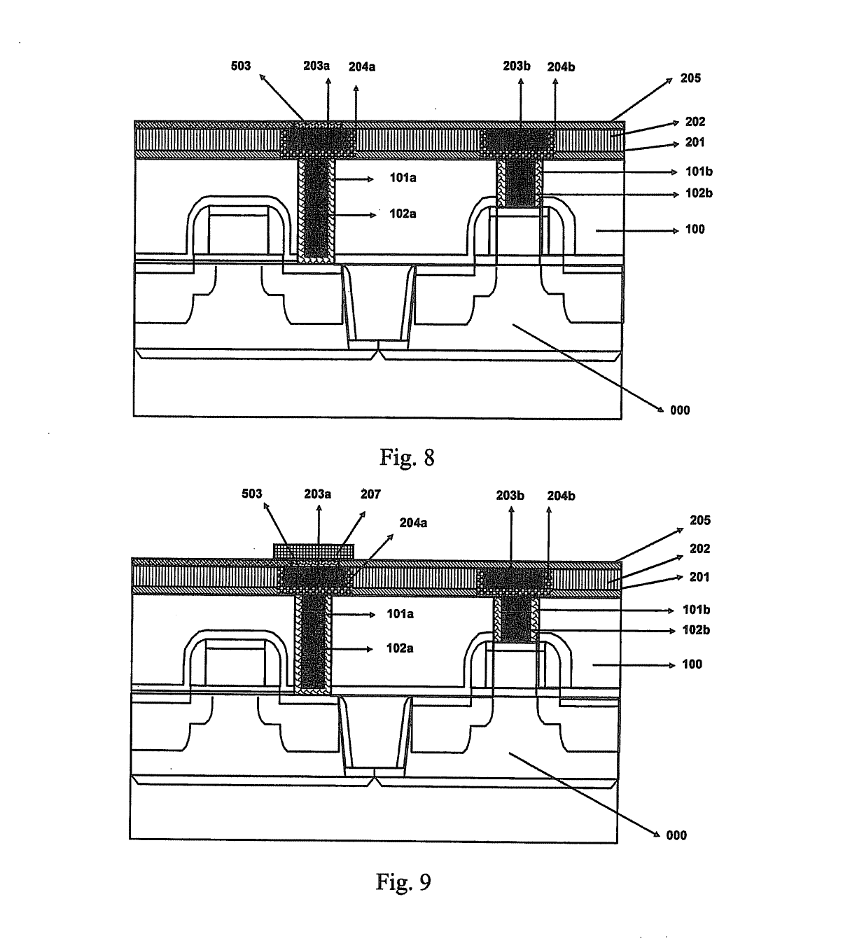

Reference is now made to FIG. 8, which is a schematic structural view after formation of MnSiₓO_{y} storage medium layer.

The MnSi compound layer 502 shown in FIG. 7 is oxidized so as to form MnSiₓO_{y} storage medium layer 503. In this embodiment, the methods of oxidizing comprise plasma oxidizing, heat oxidizing or ion implantation oxidizing. During oxidizing, the cap layer 205 simultaneously serves as a mask layer so as to protect Cu wire 203b on which it is not required to form MnSiₓO_{y} storage medium layer. The thickness range of the MnSiₓO_{y} storage medium layer 503 is 0.5 nm-50 nm, e.g., him. This method of oxidizing has a characteristic of self-aligning (the shape of the MnSiₓO_{y} storage medium layer aligns with the MnSi compound layer 502). By exposing the MnSi compound layer 502 into oxygen atmosphere or into oxygen plasma, Mn in the MnSi compound layer will react with O continuously to form MnO_{z} compound (1<z≦3). Original Si elements will exist in the MnO_{z} compound material in the form of silicon or silicon oxide so as to from MnSiₓO_{y} storage medium, i.e., the MnO_{z} based storage medium layer 503 containing doped silicon. In MnSiₓO_{y} storage medium layer 503, according to the form in which Si exists, the MnO_{z} based storage medium containing doped silicon could be a storage medium of MnO_{z} material which is doped with Si, or it could be considered as a nano complex layer of MnO_{z} and silicon oxide. The range of percentage of Si element content in MnSiₓO_{y} storage medium layer by weight is 0.001%-60%, and is specifically relevant to stoichiometric ratio of MnSi layer and process condition parameters of oxidizing. Preferably, the range of percentage of Si content in MnSiₓO_{y} storage medium layer by weight is 0.1%, 1%; and the distribution of percentage of Si content in MnSiₓO_{y} storage medium layer 503 by weight is not necessarily uniform. For example, it is possible that Si element is distributed in the MnSiₓO_{y} storage medium layer 503 in a form in which the gradient of weight percentage is gradually reduced from an upper surface to a lower surface; it is also possible that Si element is distributed in a physical layer region between the upper surface and the lower surface of the MnSiₓO_{y} storage medium layer 503 in a relatively concentrated manner. For example, the upper surface layer of the MnSiₓO_{y} storage medium layer 503 is MnO_{z} the intermediate layer is MnO_{z} containing silicon layer, and the lower surface layer is MnO_{z}. However, there is no explicit physical boundary among the upper surface layer, the intermediate layer and the lower surface layer, and therefore they all belong to the MnSiₓO_{y} storage medium layer 503. The specific distribution manner of Si element in the MnSiₓO_{y} storage medium layer 503 is not restricted by the invention. It is further noted that in addition to Si element, the MnSiₓO_{y} storage medium layer 503 may further comprise other doped elements. For example, if other active gases such as F containing gas are introduced into oxidizing gas in addition to oxygen during oxidizing, the MnO_{z} based storage medium will be doped with F in addition to contained Si. Other doped components of specific MnSiₓO_{y} storage medium layer 503 are not restricted by the embodiment of the invention and are relevant to process conditions of oxidizing.

Further, at step S80, an upper electrode is formed by patterning on the MnSiₓO_{y} storage medium layer.

Reference is now made to FIG. 9, which is a schematic structural view showing pattern-forming an upper electrode on the MnSiₓO_{y} storage medium layer. The upper electrode 207 is pattern-formed after the upper electrode metal layer is deposited. The category of upper electrode material could be conductive materials such as TaN, Ta, TiN, Ti, W, Al, Ni, Co or Mn, etc, or it could be of a complex layer structure composed of the above conductive materials. The deposition of the upper electrode metal layer could be achieved by reaction sputtering, PECVC, electron beam evaporation, etc, and the method of patterning can be achieved by photolithography.

Further, at step S90, a protective medium layer is cover-formed on the upper electrode.

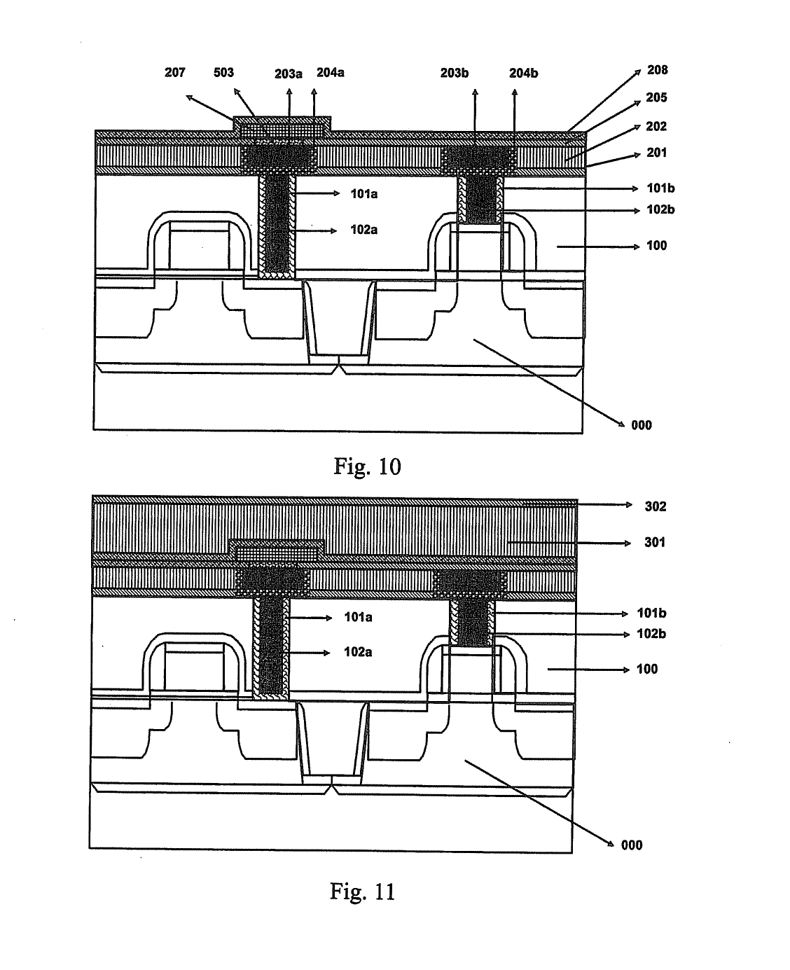

Reference is now made to FIG. 10, which is a schematic structural view after cover-forming a protective medium layer on the upper electrode. The protective medium layer 208 covers the upper electrode 207 and the cap layer 205 simultaneously. The protective medium layer 208 can prevent the upper electrode 207 from being oxidized during subsequent deposition process of dielectric layer, etc.

Further, at step S 100, a copper plug and another layer of Cu wire are formed by Damascene process.

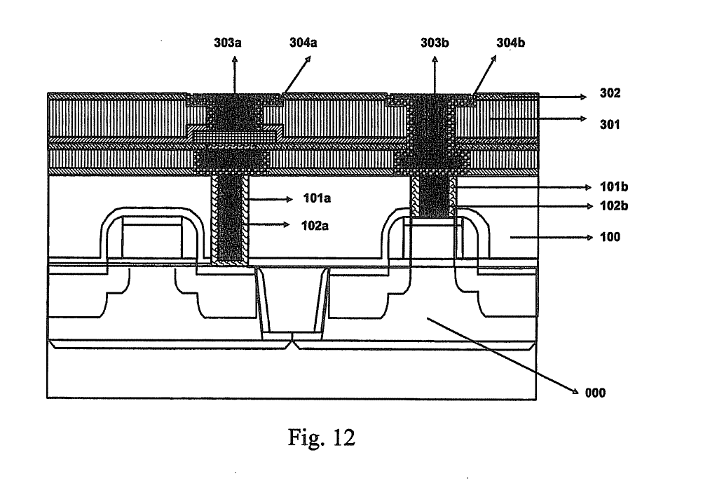

Reference is now made to FIGS. 11 and 12, wherein FIG. 11 is a schematic structural view after cover-forming a dielectric layer on the protective dielectric for forming copper plug and Cu wire, and FIG. 12 is a schematic structural view after formation of the copper plug and Cu wire. At this step, an inter-layer dielectric layer 301 and a second cap layer 302 are firstly deposited on the protective medium layer 208; then, via and trench for forming the copper plug are formed through a conventional dual Damascene process. Thereafter, the copper plug and another layer of Cu wire are formed. When forming the copper plug and the Cu wire, a method similar to the steps S201-S204 described above can be employed.

During the conventional dual Damascene process, it is noted that when fabricating the diffusion barrier layer, the process steps are the same as those used for FIG. 3, i.e., a layer of seed crystal layer of CuMn alloy is deposited, Cu is electroplated, then annealing is performed in air or oxygen containing atmosphere so as to eliminate internal defects of Cu and residual Mn atoms that have not reacted with SiO on the sidewall, and then CMP is performed so as to remove oxides on the surface of Cu wire.

Hitherto, the method for integrating resistive memory based on MnSiₓO_{y} storage medium layer with copper interconnection back-end process is substantially completed. It is noted that the above method process merely schematically describes forming a MnO_{z} based resistive memory on a first layer of Cu wire. However, the MnO_{z} based resistive memory is not limited to the situation of forming it on a first layer of Cu wire or merely on a first layer of Cu wire. For example, the MnO_{z} based resistive memory could be formed on a second layer of Cu wire and a third layer of Cu wire, which could be selected by those skilled in the art as actually required. In addition, the number of MnO_{z} based resistive memories that are integrated into the copper interconnect structure is not limited to one as shown in the figures. The specific number could be selected as actually required by circuit design.

It is noted that for the copper interconnection back-end process in the above embodiment, the dual Damascene process is preferably employed. However, the method of the invention for integrating with copper interconnect back-end process is not limited to the dual Damascene process. For example, the single Damascene process can also be employed.

In the above method process, by integrating MnO_{z} based resistive memory with a copper interconnection back-end process, the resistive memory of MIM (metal-insulator-metal) structure is embedded into the copper interconnect back-end structure of logic circuit, especially into a copper interconnect back-end structure at or below 45 nm process node. Therefore, a perfect compatibility between logic process and memory manufacture process can be achieved so that manufacture cost is reduced. On the other hand, since a process of first silicifying and then oxidizing Mn metal layer is employed for MnO_{z} based resistive memory, the speed of oxidizing is relatively slow, the controllability of process is better, and the yield rate and reliability of MnSiₓO_{y} storage medium layer are improved; moreover, due to the relative denser characteristic of MnSi, the MnSiₓO_{y} storage medium layer after oxidization is more dense than common Mn oxides. Thus, resistances in both high resistance state and low resistance state are improved (especially in low resistance state), thereby lowering power consumption of memory unit.

The above embodiments mainly describe the method for process integrating of the invention. Though some of the embodiments of the invention have been described, those skilled in the art will understand that the invention can be implemented in many other forms without departing from its spirit and scope. Therefore, the illustrated examples and embodiments should be considered as schematic rather than being limiting. The invention can cover various modifications and substitutes without departing from the spirit and scope of the invention defined by appended claims.

1. A method for integrating MnO_{z} based resistive memory with copper interconnection back-end process, characterized in that the method comprises the following steps:
(1) pattern-forming Cu wire having MnSiO compound layer as barrier layer;
(2) cover-depositing cap layer on the Cu wire;
(3) pattern-etching the cap layer to form apertures so as to expose Cu wire region where MnSiₓO_{y} storage medium layer is intended to be formed;
(4) filling Mn metal layer in the apertures of the cap layer;
(5) silicifying the Mn metal layer to form MnSi compound layer;
(6) oxidizing the MnSi compound layer to form MnSiₓO_{y} storage medium layer;
(7) pattern-forming an upper electrode on the MnSiₓO_{y} storage medium layer; and
(8) continuing with the copper interconnection back-end process to form copper plug and a next layer of Cu wire;
wherein 0.001<x≦2, 2<y≦5.

2. The method according to claim 1, characterized in that the copper interconnection back-end process is a process at or below 45 nm process node.

3. The method according to claim 1, characterized in that said step (1) comprises the following steps:
(1a) depositing seed crystal layer of CuMn alloy in the trench;
(1b) electroplating copper;
(1c) annealing copper and the seed crystal layer of Cu and Mn alloy;
(1d) conducting planarization to remove excessive copper and copper oxide and Mn oxide in the surface of Cu wire.

4. The method according to claim 1, characterized in that said silicifying is silicifying in-silicon containing gas, silicifying in silicon plasma or ion implantation silicifying of silicon.

5. The method according to claim 1, characterized in that said oxidizing is one of plasma oxidizing, heat oxidizing, ion implantation oxidizing.

6. The method according to claim 1, characterized in that the upper electrode is a metal layer of TaN, Ta, TiN, Ti, W, Al, Ni, C or Mn, or a complex layer composed of a plurality of layers of the above metal layers.

7. The method according to claim 1, characterized in that the Mn metal layer is obtained by sputtering, evaporation or electroplating deposition, and the thickness range of Mn metal layer is from about 0.5 nm to about 50 nm.

8. The method according to claim 1, characterized in that the MnSiₓO_{y} storage medium layer is a storage medium layer formed by doping Si into MnO_{z} wherein 1<z≦3.

9. The method according to claim 1, characterized in that the MnSiₓO_{y} storage medium layer is a nano complex layer of MnO_{z} and silicon oxide, wherein 1<z≦3.

10. The method according to claim 1, characterized in that the copper interconnection back-end process employs dual Damascene process.
